(19) United States
(12) Patent Application Publication
(10) Pub. No.: US 2009/0191688 A1
(43) Pub. Date: Jul. 30, 2009

(54) Shallow Trench Isolation Process Using Two Liners

(75) Inventors: Binghua Hu, Plano, TX (US); Billy A. Wofford, Dallas, TX (US); Tan Q. Pham, Allen, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/020,957

(22) Filed: Jan. 28, 2008

(51) Int. Cl. H01L 21/76

(52) U.S. Cl. 438/424; 257/E21.54

(57) ABSTRACT

A method for making STI structure includes etching a STI trench through a nitride layer, through an oxide layer, and into a silicon layer. The method also includes forming a sacrificial liner, pulling-back the nitride layer, and removing a remaining portion of the sacrificial liner. Furthermore, the method includes forming a STI liner and forming a STI fill coupled to the STI liner.

### BACKGROUND OF THE INVENTION

This invention relates to the fabrication of a Shallow Trench isolation (“STI”) structure for System-On-Chip (“SOC”) applications, such as low power, high power, and flash devices.

### BRIEF DESCRIPTION OF THE DRAWINGS

FIG. 1 is a cross-sectional view of a semiconductor wafer in accordance with the present Invention.

FIG. 2A-2L are cross-sectional diagrams of a process for forming a STI structure in accordance with the present invention.

### DETAILED DESCRIPTION OF THE INVENTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

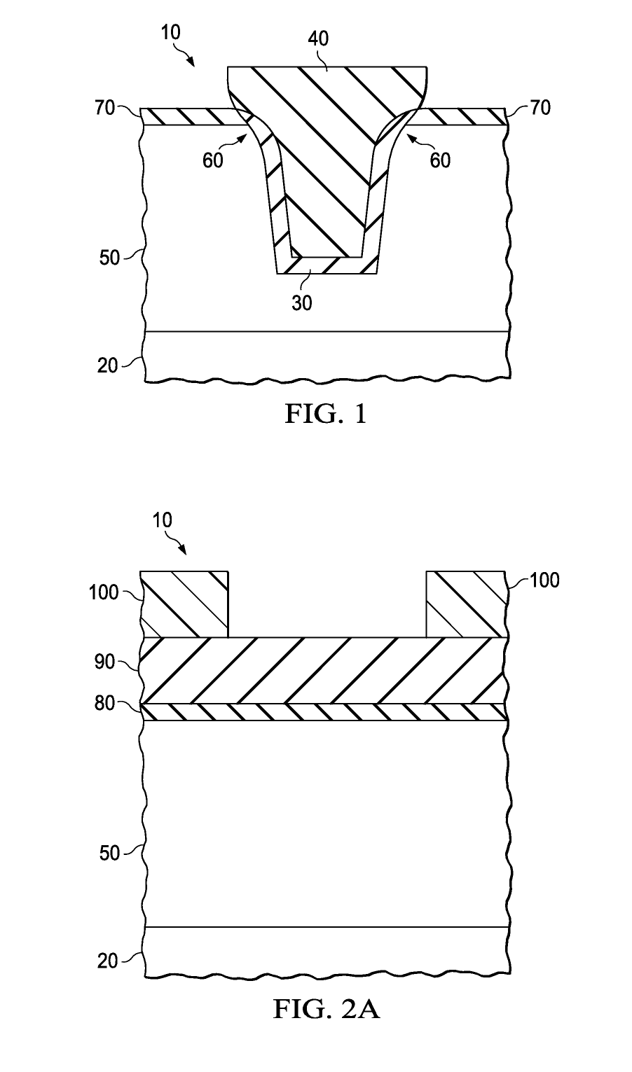

Referring to the drawings, FIG. 1 is a cross-sectional view of a semiconductor wafer 10 containing a STI (“Shallow Trench Isolation”) structure 30, 40 in accordance with an embodiment of the present invention. In general, STI structures 30, 40 electrically isolate the active devices formed within the semiconductor wafer 10. Examples of active devices are low-voltage CMOS (“Complementary Metal Oxide Semiconductor”), high-voltage LDMOS (“Laterally Diffused Metal Oxide Semiconductor”), DECMOS (“Drain Extended Complementary Metal Oxide Semiconductor”), and flash, in the example application, a STI structure 30, 40 is formed within a semiconductor substrate 20 having a silicon layer 50. The silicon layer 50 may be a portion of a (doped) epitaxial layer that was grown on a substrate base of crystalline silicon 20. Furthermore, the silicon layer 50 may include a p-well or an n-well region formed within the epitaxial layer (that was grown on a substrate base 20).

The example STI structure 30, 40 is comprised of an STI liner 30 and a STI fill 40. More specifically, the STI liner 30 is thermally formed and is comprised of silicon oxide material. The thickness of the STI liner 30 may vary between 100-250 Å. The STI fill 40 is comprised of high density silicon oxide that is used to fill the trench that exists after the formation of the STI liner 30. Therefore, the STI fill 40 has a final thickness that is dependant on the targeted width of the STI structure and the targeted height of the STI CMP (“Chemical Mechanical Polish”) process.

It Is to be noted that the STI structure 30, 40 formed in accordance with the invention has a rounded corner 80 towards the top surface of the silicon layer 50. Conversely, traditional STI structures have relatively sharp corners towards the top surface of the silicon layer 50. As a result, the STI structure 30, 40 of the present invention may improve device reliability through improved gate oxide integrity, an ability to handle high voltages, the ability to endure more power cycles, and decreased physical stresses at the interface between the STI structure and the top portion of the silicon layer 50.

As shown in FIG. 1, a gate oxide layer 70 is formed over the active regions of the semiconductor wafer 10 (which are the exposed surfaces of the silicon layer 50 that are located between the STI structures 30, 40). When the fabrication of the semiconductor wafer 10 is complete, the gate oxide layer 70 will function as the gate dielectric for the transistors (not shown) that are formed in the semiconductor wafer 10. The STI structure 30, 40 of the present invention may improve device performance by reducing the leakage from a subsequently formed transistor gate electrode to the silicon layer 50 through the gate oxide layer 70.

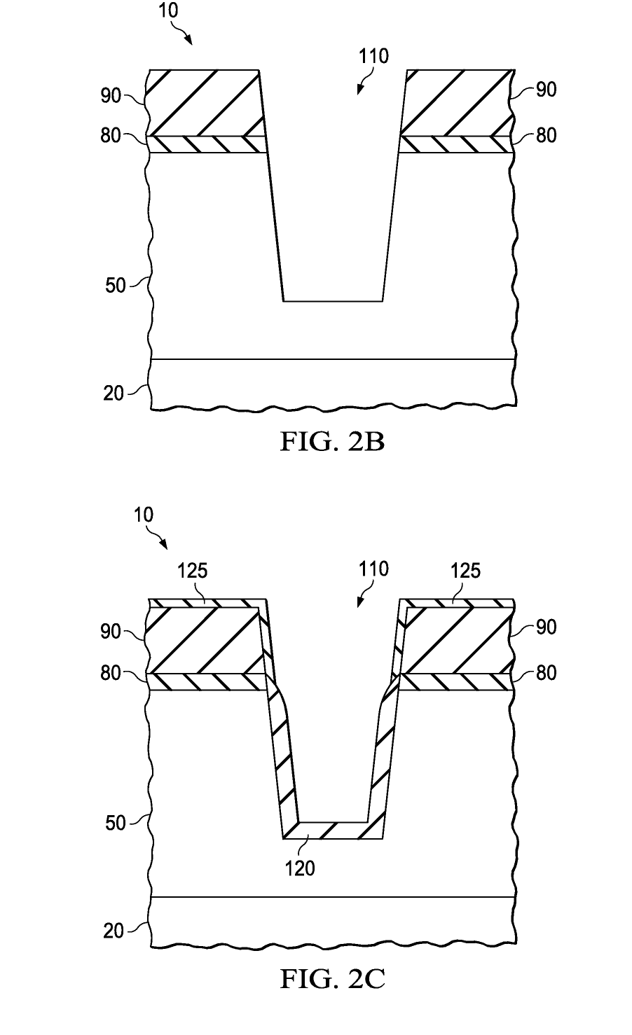

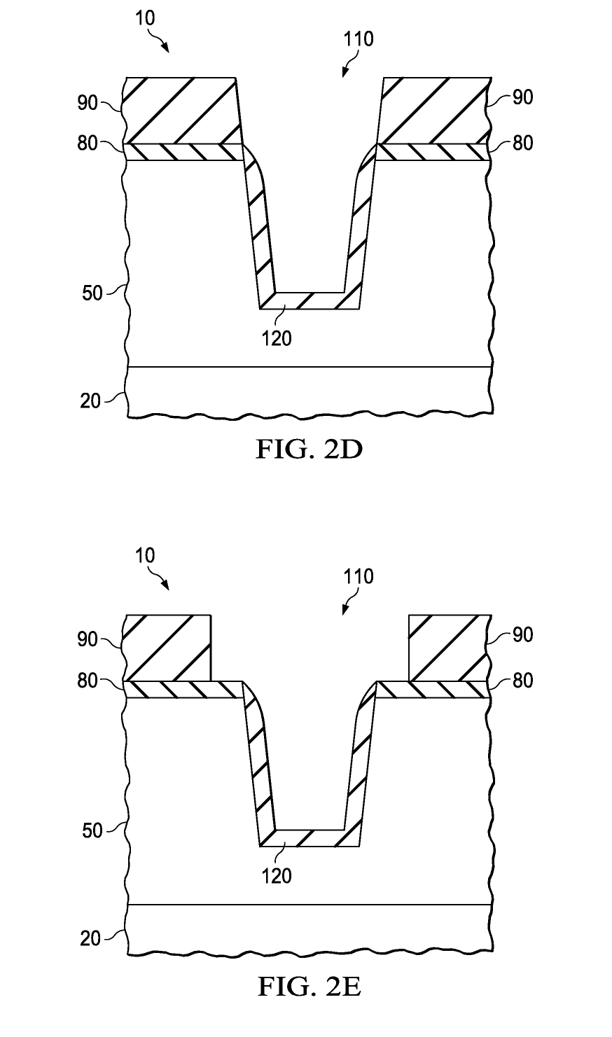

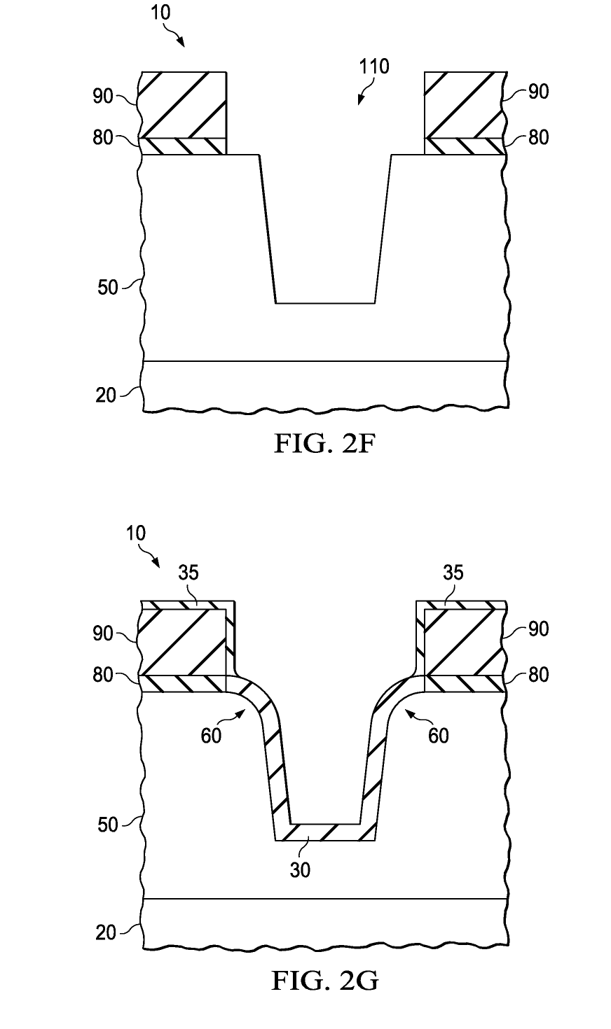

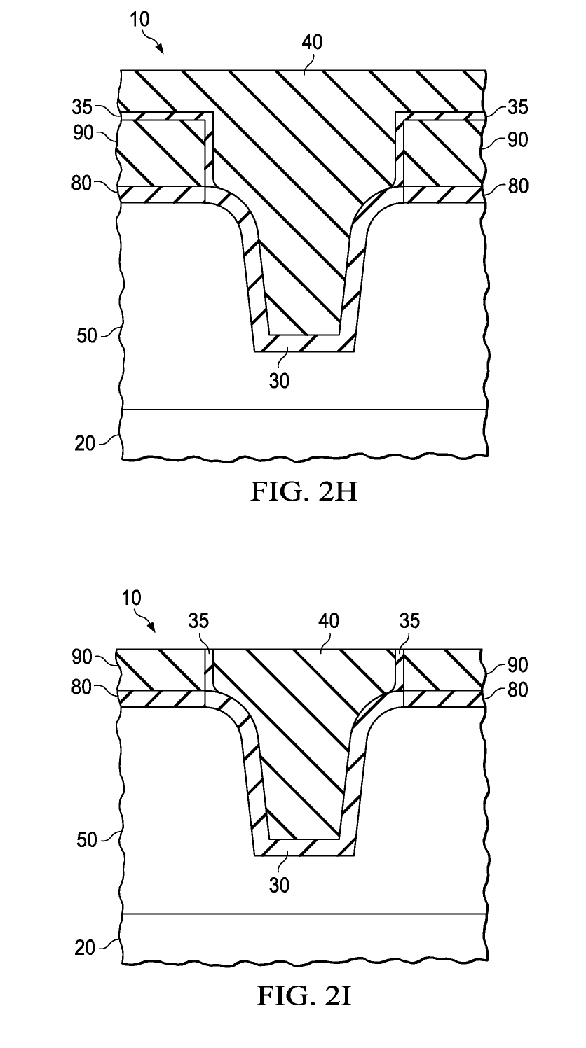

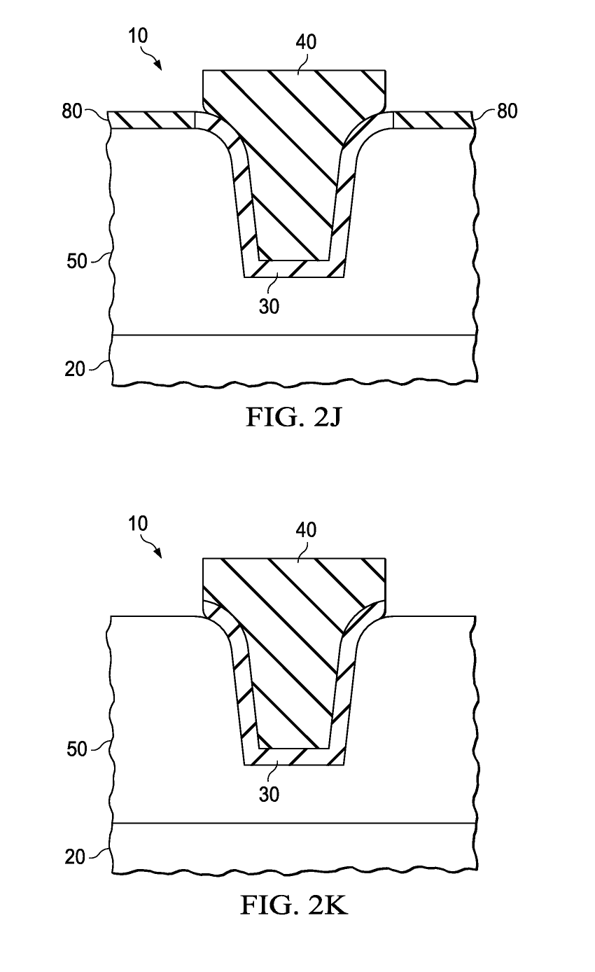

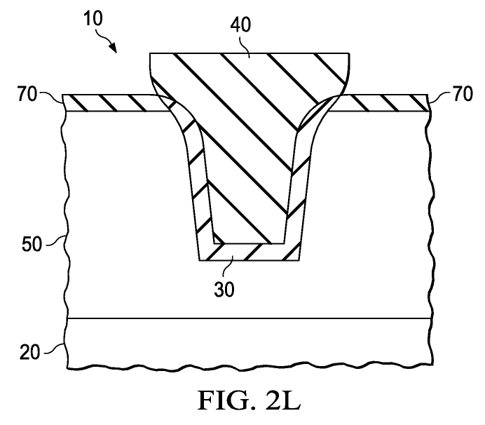

Referring again to the drawings, FIGS. 2A-2L are cross-sectional views of a partially fabricated semiconductor wafer 10 illustrating a process for forming an example STI structure 30, 40 in accordance with the present invention. The example application is exemplary, but not restrictive, of alternative ways of implementing the principles of the invention. Moreover, features and processes that are well known to those skilled In the art are omitted for brevity. For example, the implementation of common fabrication steps lies within the ability of those skilled in the art; accordingly, any detailed discussion thereof may be omitted.

FIG. 2A is a cross-sectional view of the semiconductor wafer 10 after the formation of an oxide layer 80 and a nitride layer 90 on the top surface of a silicon layer 50 (that overlies a semiconductor substrate 20). The oxide layer 80 and the nitride layer 90 are formed using well-known manufacturing techniques. The first layer formed over the surface of the silicon layer 50 is an oxide layer 80. In the example application, the oxide layer 80 is comprised of a thermal silicon dioxide and it has a thickness between 50-200 Å. The oxide layer 80 is formed with any standard process, such as a thermal oxidation process. However, the oxide layer 80 may be formed using any one of a variety of standard processes such as an oxidation process.

A nitride layer 90 is then formed on the surface of the oxide layer 80. The nitride layer 90 is comprised of silicon nitride and it is 1000-3000 Å thick in the example application. The nitride layer 90 may be formed using any standard process such as low pressure chemical vapor deposition (“LPCVD”).

A patterned photoresist layer 100 is formed over the nitride layer 90, as shown in FIG. 2A. The photoresist layer 100 is comprised of standard photoresist material and it may include an anti-reflective coating. The photoresist layer 100 is patterned to expose the surface of the nitride layer 90 that covers the targeted location of the STI structure.

After a standard dry etch process (or possibly multiple etch processes), a STI trench 110 will be formed through the nitride layer 90, through the oxide layer 80, and partially into the silicon layer 50, as shown in FIG. 2B. The patterned photoresist layer 100 is then removed using a standard ash and clean technique (as also shown in FIG. 2B). It is to be noted that the sidewalls of the STI trench 110 may be slightly slanted because standard dry etch processes are slightly anisotropic.

As shown in FIG. 2C, the next step is the formation of a conformal sacrificial liner 120. The sacrificial liner 120 is formed using a standard thermal oxidation process. In the example application, the sacrificial liner 120 has a thickness between 50-150 Å. The sacrificial liner 120 that is formed within the surface of the oxide layer 80 and the exposed surface of silicon layer 50 is comprised of silicon oxide. It is to be noted that a thin layer of oxynitride 125 will also be formed within the exposed surface of the nitride layer 90 during the same thermal oxidation process, as shown in FIG. 2C.

The next step In the fabrication of the STI structure is the removal of the oxynitride layer 125 and the pulling-back of the nitride layer 90 to facilitate the exposure of a portion of the top surface of the silicon layer 50 during the thermal oxidation step that forms the conformal STI liner 30 (described infra), in the example application, this is accomplished with a two step process, in the first step, shown in FIG. 2D, a wet etch process is used to remove the oxynitride layer 125. More specifically, a hydrofluoric acid (e.g. HF) strip is used to anisotropically remove the oxynitride layer 125 from the surfaces of the nitride layer 90. It is to be noted that this strip will not remove the majority of the sacrificial liner 120 from the surface of the oxide layer 80. Furthermore, the sacrificial liner 120 will continue to exist at the surface of the silicon layer 50 in the STI trench 110 (as shown).

The second step in the nitride pull-back process is the anisotropic removal of the exposed surfaces of the nitride layer 90. As shown in FIG. 2E, a suitable etch process, such as a standard hot phosphoric acid (e.g. H₃PO₄) nitride strip, is used to move the edges of the nitride layer 90 back about 50-200 Å from the sidewalls of the STI trench 110. Because the hot phosphoric acid process is selective to silicon oxide, the oxide layer 80 will be largely unaffected by this phosphoric nitride strip process. Moreover, the silicon oxide sacrificial liner 120 will protect the silicon layer 50 from unwanted phosphorous contamination (i.e. the sacrificial liner 120 will contain the phosphorous molecules until the phosphorous-containing sacrificial liner 120 is removed).

Once the nitride pull-back process is complete, a standard wet etch process is used to remove any exposed silicon oxide material—including the remainder of the sacrificial oxide liner 120 within the STI trench 110 and the exposed portion of oxide layer 80. In the example application, another standard hydrofluoric etch is used for this wet etch process. As shown in FIG. 2F, the top corners of the STI trench 110 within the silicon layer 50 will be exposed after this wet etch process is complete. The semiconductor wafer 10 is now ready for the formation of the conformal STI liner 30.

As shown in FIG. 2G, the conformal STI liner 30 is now formed within silicon layer 50 using any suitable process. Preferably, the conformal STI liner 30 is formed by adding a few percent of trans 1,2 dichioroethene to a dry O₂ ambient during a high temperature thermal oxidation process. In the example application, the STI liner 30 has a thickness between 100-250 Å and it is comprised of silicon oxide. In addition, this thermal oxidation process will create a thin layer of oxynitride 35 within the surface of the nitride layer 90.

It is to be noted that the thermal oxidation process used to form the STI liner 30 will cause the top corners 80 of the trench within the silicon layer 50 to be rounded. This change in the structure of the silicon layer 50 occurs because the horizontal surfaces (and the vertical surfaces) of the silicon layer 50 were exposed by the previous wet etch process (as shown in FIG. 2F), so both surfaces will be oxidized. More specifically, the presence of the few percent of trans 1,2 dichioroethene during the high temperature thermal oxidation step will facilitate an enhanced oxidation rate at the moat corner 80 (as shown in FIG. 2G). Therefore, both the horizontal and the vertical surfaces of the silicon layer 50 are consumed by the conversion of silicon into silicon oxide during the high temperature thermal oxidation process.

The remainder of the STI trench 110 is now plugged by the formation of the STI fill 40, as shown In FIG. 2H. The STI fill 40 may be comprised of any suitable material, such as silicon oxide, and it may be formed with any suitable process. For example, a layer of STI fill may be deposited using a standard high density plasma oxide process (“HDP fill”). Alternatively, the semiconductor wafer 10 shown in FIG. 2G may be annealed and then subjected to an atmospheric pressure chemical vapor deposition process (“APCVD”) to form the STI fill layer 40 of FIG. 2H.

As shown in FIG. 2I, the STI fill layer 40 is then continuously planarized by a STI CMP process that is selective to oxide. The CMP process generally stops after 30-60% of the nitride layer 90 is consumed.

The semiconductor wafer 10 is now prepared for the formation of additional device structures by removing the nitride layer 90 and the oxynitride layer 35. Specifically, the nitride layer 90 and the oxynitride layer 35 are etched with any standard process, such as a wet etch, as shown in FIG. 2J. Then, as shown in FIG. 2K, the exposed oxide layer 80 is removed by any standard process, such as an additional wet etch, so that the surface of silicon layer 50 is prepared for further processing. It is within the scope of the invention to perform commonly known additional steps, such as an oxide deglaze (to remove any remaining oxide) and a pre-furnace clean, at this stage in the manufacturing process.

The fabrication of the semiconductor wafer 10 now continues (using standard process steps) until the semiconductor device Is complete. As shown in FIG. 2L, the next step would probably be the formation of the gate oxide layer 70 (generally 70-300 Å thick) on the exposed surfaces of silicon layer 50. Subsequent fabrication steps will form the gate electrode and the source/drain regions of the device transistors.

Once the transistor is complete, the STI structure 30, 40 may improve device performance by increasing the hard breakdown voltage from a transistor gate electrode formed over the gate oxide 70 to its underlying silicon layer 50. In addition, the rounded corners 60 of the STI structure 30, 40 may facilitate an increased thickness of the gate oxide 70 at the corner locations (as compared to traditional STI structures that have sharper top corners). As a result, the lifetime reliability of the final device may be increased (i.e. improved tolerance for higher power levels and additional power cycles).

Various additional modifications to the invention as described above are within the scope of the claimed invention. As an example, an anneal process may be performed after any step in the above-described fabrication process. When used, the anneal process can improve the microstructure of materials and thereby improve the quality of the semiconductor structure.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A method for making a STI structure, comprising:
providing a semiconductor substrate containing a silicon layer, an oxide layer coupled to said silicon layer, and a nitride layer coupled to said oxide layer;
etching a STI trench through said nitride layer, through said oxide layer, and into said silicon layer;
forming a sacrificial liner and an oxynitride layer over said semiconductor substrate;
pulling-back said nitride layer;
removing a remaining portion of said sacrificial liner to expose portions of said silicon layer;
forming a STI liner over said exposed portions of said silicon layer; and
forming a STI fill coupled to said STI liner.

2. The method of claim 1 wherein said semiconductor substrate also contains wells.

3. The method of claim 1 wherein said sacrificial liner contains oxide and has a thickness between 50-150 Å.

4. The method of claim 1 wherein said step of pulling-back said nitride layer comprises:
removing said oxynitride layer with a wet etch process; and
pulling-back said nitride layer with an acid strip process.

5. The method of claim 1 wherein said step of pulling-back said nitride layer will pull back an edge of said nitride layer a distance of 50-200 Å from an edge of said STI trench.

6. The method of claim 1 wherein said step of removing said remaining portion of said sacrificial liner comprises a wet etch process.

7. The method of claim 1 wherein said STI liner is comprised of silicon oxide and has a thickness between 100-250 Å.

8. The method of claim 1 wherein said step of forming said STI fill comprises:
annealing said STI liner; and
forming said STI fill using a HDP fill process.

9. The method of claim 1 wherein said step of forming said STI fill comprises an APCVD process.

10. The method of claim 1 further comprising a step of performing a STI CMP process after said step of forming said STI fill.
